(19) United States
(12) Patent Application Publication
(10) Pub. No.: US 2026/0033333 A1
(43) Pub. Date: Jan. 29, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Yuto UEMATSU, Matsumoto-city (JP); Yushi SATO, Matsumoto-city (JP)

(73) Assignee: FUJI ELECTRIC CO., LTD., Kawasaki-shi (JP)

(21) Appl. No.: 19/223,650

(22) Filed: May 30, 2025

(30) Foreign Application Priority Data
Jul. 29, 2024 (JP) 2024-122911

(51) Int. Cl. H01L 23/367; H01L 23/00; H01L 23/473

(52) U.S. Cl. CPC H01L 23/3672; H01L 23/473; H01L 24/32; H01L 2224/32113; H01L 2224/32227; H01L 2224/32238; H01L 2924/3511; H01L 2924/3512

(57) ABSTRACT

A semiconductor device, including: a stacked substrate; a semiconductor device element mounted on the stacked substrate via a first bonding layer; a metal base bonded to the stacked substrate via a second bonding layer, the metal base having two ends and a center portion; and a water jacket bonded to the metal base. The first and second bonding layers are identical, or different, in a material and a composition thereof. The metal base has a plurality of heat dissipation fins, lengths of which are in an ascending order from each of the ends to the center portion of the metal base.

### CROSS REFERENCE TO RELATED APPLICATIONS

This application is based upon and claims the benefit of priority of the prior Japanese Patent Application No. 2024-122911, filed on Jul. 29, 2024, the entire contents of which are incorporated herein by reference.

### BACKGROUND OF THE INVENTION

### 1. Field of the Invention

Embodiments of the disclosure related to a semiconductor device and a method of manufacturing a semiconductor device.

### 2. Description of the Related Art

Conventionally, a cooling device for electronic components has been proposed in which heat dissipation fins are longest at a center of a power device and are progressively shorter toward each end, whereby pressure loss of a cooling fluid is suppressed and a desired cooling performance is maintained even when a semiconductor device thereof is miniaturized. For example, refer to Japanese Laid-Open Patent Publication No. 2003-008264.

### SUMMARY OF THE INVENTION

According to an embodiment of the present disclosure, a semiconductor device includes: a stacked substrate; a semiconductor device element mounted on the stacked substrate via a first bonding layer; a metal base bonded to the stacked substrate via a second bonding layer, the metal base having two ends and a center portion; and a water jacket bonded to the metal base. The first and second bonding layers are identical, or different, in a material and a composition thereof. The metal base has a plurality of heat dissipation fins, lengths of which are in an ascending order from each of the ends to the center portion of the metal base.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor module according to an embodiment.

FIG. 2 is a cross-sectional view depicting a warped state of the semiconductor module according to the embodiment.

FIG. 3 is a cross-sectional view depicting a state after fastening of a water jacket of the semiconductor device according to the embodiment.

FIG. 4 is an enlarged view of a cross-section of heat dissipation fins of the semiconductor device according to the embodiment in a state after fastening of the water jacket.

FIG. 5 is a graph depicting variation evaluation of thermal resistance of a metal base according to the embodiment.

FIG. 6 is a top view depicting thermal resistance variation measurement positions of the metal base according to the embodiment.

FIG. 7 is a cross-sectional view depicting a structure of a conventional semiconductor module.

FIG. 8 is a cross-sectional view depicting a warped state of the conventional semiconductor module.

FIG. 9 is a cross-sectional view depicting a state of the conventional semiconductor device before fastening of a water jacket.

FIG. 10 is a cross-sectional view depicting a state of the conventional semiconductor device after fastening of the water jacket.

FIG. 11 is an enlarged view of heat dissipation fins in a state after water jacket fastening of the conventional semiconductor device.

### DETAILED DESCRIPTION OF THE INVENTION

First, problems associated with the conventional techniques are discussed. In a conventional semiconductor device, a problem arises in that when a semiconductor module is deformed into a convex shape by fastening a water jacket (WJ) or the like, gaps (clearance) between the water jacket and heat dissipation fins (tips) at a center portion of the semiconductor module and gaps (clearance) between the water jacket and heat dissipation fins (tips) at opposite ends of the semiconductor module differ, resulting in a difference in cooling performance, whereby thermal resistance varies.

An outline of the present disclosure is described. A semiconductor device according to the present disclosure solving the described problems and achieving an object has the following features. The semiconductor device includes a stacked substrate on which a semiconductor device element is mounted via a first bonding layer; a metal base bonded to the stacked substrate via a second bonding layer of a material and composition a same as or different from a material and composition of the first bonding layer, the metal base having a plurality heat dissipation fins; and a water jacket bonded to the metal base. The heat dissipation fins are formed so as to be in ascending order of length from ends of the metal base to a center portion of the metal base.

According to the disclosure above, the clearance is constant regardless of the locations where the power semiconductor chips of the semiconductor module are disposed. Thus, no difference in the cooling capability by the heat dissipation fins and the water jacket at the center portion and at the ends of the semiconductor module occurs, whereby reliability of the semiconductor device may be improved without variation of the thermal resistance.

Further, in the semiconductor device according to the present disclosure, in the disclosure above, the metal base is convex in a direction to the semiconductor device element.

Further, in the semiconductor device according to the present disclosure, in the disclosure above, an amount of warpage of the metal base is 0.1 mm or more.

Further, in the semiconductor device according to the present disclosure, in the disclosure above, a clearance between a floor of the water jacket and respective tips of the plurality of heat dissipation fins is less than 0.2 mm.

Further, in the semiconductor device according to the present disclosure, in the disclosure above, a clearance between a floor of the water jacket and respective tips of the plurality of heat dissipation fins is less than 0.1 mm.

Further, in the semiconductor device according to the present disclosure, in the disclosure above, a maximum thermal resistance variation of the metal base is not more than 1.1.

Further, in the semiconductor device according to the present disclosure, in the disclosure above, a maximum thermal resistance variation of the metal base is not more than 1.06.

A method of manufacturing a semiconductor device according to the present disclosure solving the described problems and achieving an object has the following features. First, a first process of mounting a semiconductor device element on a stacked substrate via a first bonding layer is performed. Next, a second process of bonding a metal base having a plurality of heat dissipation fins to the stacked substrate via a second bonding layer of a material and composition a same as or different from a material and composition of the first bonding layer is performed. Next, a third process of bonding a water jacket to the metal base is performed. An adjusting process of measuring an amount of warpage of the metal base before the bonding the metal base, and adjusting lengths of the plurality of heat dissipation fins according to the amount warpage so that the plurality of heat dissipation fins is disposed in ascending order of the lengths, from ends of the metal base to a center portion of the metal base is performed.

Further, in the method of manufacturing a semiconductor device according to the present disclosure, in the disclosure above, the adjusting process includes bonding a test water jacket to the metal base, measuring a distance from a floor of the test water jacket to a tip of each of the plurality of heat dissipation fins or measuring a distance from the floor of the test water jacket to a back surface of the metal base, and adjusting the lengths of the plurality of heat dissipation fins so that the measured distance becomes constant.

Further, in the method of manufacturing a semiconductor device according to the present disclosure, in the disclosure above, the adjusting process includes adjusting a length L(x) of each of the plurality of heat dissipation fins to satisfy L(x)=L(0)+(C(x)−C(0)), the each of the plurality of heat dissipation fins being at a position x; L(0) being a length of a closest one of the plurality of heat dissipation fins, the closest one being, of the plurality of heat dissipation fins, closest to an end; C(x) being a distance from a floor of the test water jacket to a tip of the each of the plurality of heat dissipation fins at the position x; C(0) being a distance from the floor of the test water jacket to a tip of the closest one of the plurality of heat dissipation fins.

Findings underlying the present disclosure are discussed. First, problems associated with conventional semiconductor devices are further described. FIG. 7 is a cross-sectional view depicting a structure of a conventional semiconductor module. As depicted in FIG. 7, a semiconductor module 150 includes a power semiconductor chip 101, a stacked substrate 105, a case 107, a metal base 126, metal terminals 109, and metal wires 110. The power semiconductor chip 101 is a power semiconductor chip of, for example, a metal-oxide-semiconductor field effect transistor (MOSFET), an insulated-gate bipolar transistor (IGBT), or a diode and is bonded on the stacked substrate 105 by a bonding layer 125 constituted by a solder or the like. In the stacked substrate 105, a first conductive plate 103 containing, for example, copper, is provided on a front surface of an insulating substrate 102 such as a ceramic substrate and a second conductive plate 104 containing, for example, copper, is provided on a back surface of the insulating substrate 102. The stacked substrate 105 is bonded to the metal base 126 by the bonding layer 125 constituted by a solder or the like. The metal terminals 109, which lead signals to an external destination, are disposed so as to pass through an inside of the case 107 and be exposed in the case. The metal wires 110 electrically connect the power semiconductor chip 101 and the metal terminals 109. Further, at a surface of the power semiconductor chip 101, a source electrode pad is formed as a power terminal electrode pad (current supply terminal) in an instance of a MOSFET. Further, a conductive connecting member such as a lead frame or the metal wires 110 is disposed as an output terminal from the power terminal electrode pad. In an instance of a lead frame, the bonding layer 125 constituted by, a solder or the like, bonds the lead frame to the power semiconductor chip 101. While not depicted, these members are each mounted in plural in a single semiconductor module. The semiconductor module 150 is provided with a non-depicted cover to which the case 107 is adhered and through which the metal terminals 109 penetrate to the exterior. The case 107 is filled with an encapsulating resin (encapsulating material) 108 that insulates and protects each stacked substrate 105 and the power semiconductor chips 101 on the stacked substrate 105.

At a back surface of the metal base 126, multiple heat dissipation fins 128 are provided. The metal base 126 conducts heat to the heat dissipation fins 128, the heat being generated in the power semiconductor chip 101 and transmitted through the stacked substrate 105. The heat dissipation fins 128 dissipate the heat conducted from the metal base 126, through a cooling medium or the like.

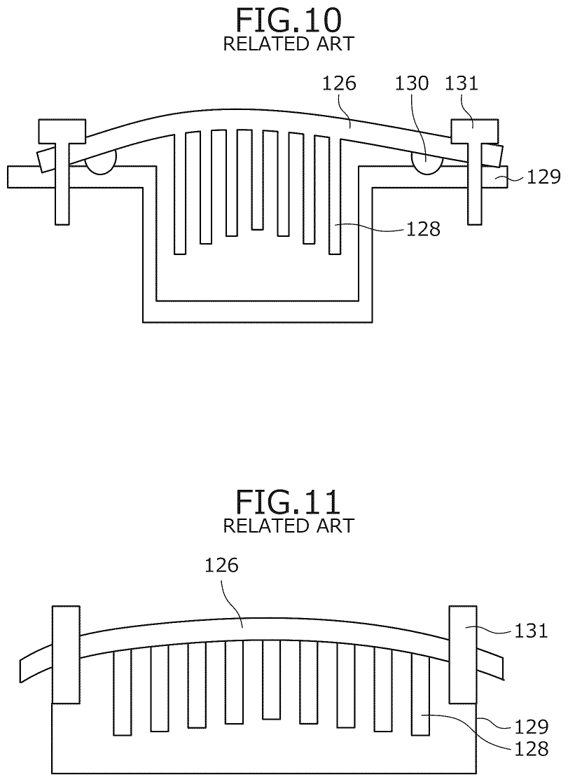

By itself, the semiconductor module 150 cannot flow the cooling medium because the metal base 126 is open. Thus, the semiconductor module 150 is attached to a separate water jacket 129 for cooling (refer to FIGS. 9 and 10) and the cooling medium flows. When the semiconductor module 150 is operated, heat is generated in the power semiconductor chip 101. Thus, by operating the semiconductor module 150 while flowing and cooling the cooling medium, the heat generated in the power semiconductor chip 101 is controlled, enabling operation within a guaranteed chip temperature range. Thermal resistance during cooling varies depending on cooling capacity; clearance between the water jacket 129 and the heat dissipation fins 128 of the metal base 126 decreases depending on the heat dissipation fins 128; and the heat dissipation fins 128 are disposed on all flow paths to increase cooling performance.

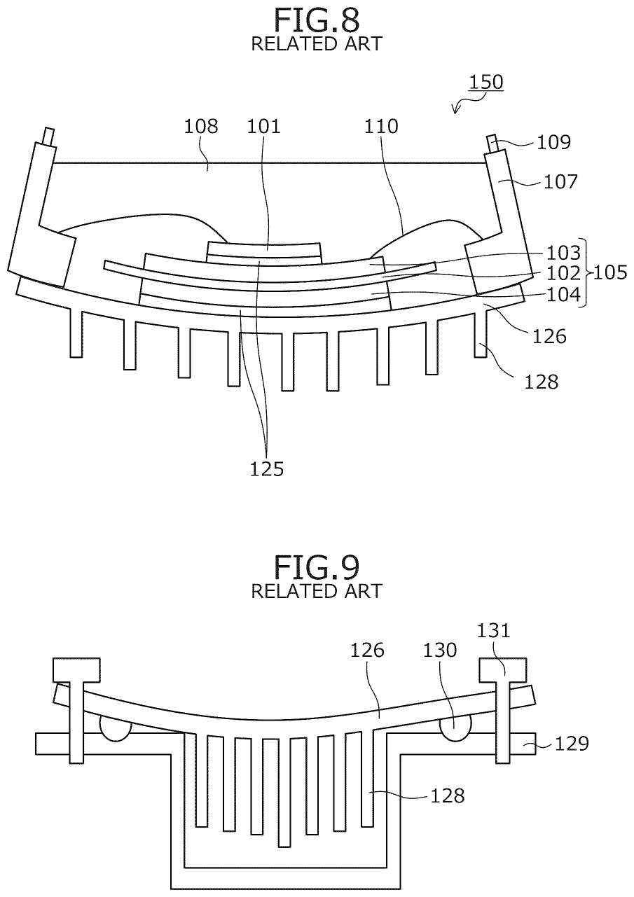

FIG. 8 is a cross-sectional view depicting a warped state of the conventional semiconductor module. As depicted in FIG. 8, when a bonding process such as soldering with a heat treatment is performed to the metal base 126 and the stacked substrate 105 on which the power semiconductor chip 101, the metal wires 110, etc. are mounted, due to a difference in respective linear expansion coefficients, the stacked substrate 105 warps together with the metal base 126 and the semiconductor module 150 also warps, resulting in a convex downward warped state.

FIG. 9 is a cross-sectional view depicting a state of the conventional semiconductor device before fastening of the water jacket. Here, the semiconductor device refers to one having the semiconductor module and the water jacket. In FIG. 9 and FIG. 10 described below, the structure above the metal base 126 is not depicted. The semiconductor module 150 is fastened to the water jacket 129 by fastening screws 131, via a sealing member such as a gasket or an O-ring 130 between the semiconductor module 150 and the water jacket 129.

FIG. 10 is a cross-sectional view depicting a state of the conventional semiconductor device after fastening of the water jacket. Since the water jacket 129 is fastened at four locations by fastening screws, the center portion of the semiconductor module 150 becomes deformed in a convex upward state due to the reaction force and internal pressure of the gasket and the O-ring 13. As described, the warpage is not corrected even when the warped semiconductor module 150 is fastened to the water jacket 129 but rather occurs in the reverse direction. Herein, “convex upward” refers to a shape that is warped in a convex shape such that an upper side facing the power semiconductor chip 101 protrudes in a direction to the power semiconductor chip 101 assumed to be thereabove while the “reverse direction” refers to a shape that is “convex downward”.

FIG. 11 is an enlarged view of the heat dissipation fins in a state after water jacket fastening of the conventional semiconductor device. As depicted in FIG. 11, the center portion of the semiconductor module 150 is in a convex upward state and thus, gaps (clearance) between tips of the heat dissipation fins 128 and a bottom (floor: inner surface of a bottom plate) of the water jacket 129 become wider in the center portion, and in-plane variation of the cooling efficiency (thermal resistance) occurs at the ends and the center portion. In-plane variation of the cooling efficiency (thermal resistance) occurs at the ends and the center portion of the semiconductor module 150, resulting in a difference in the cooling capability at the ends and the center portion, whereby variation (value at the center portion is large) in the thermal resistance of the metal base 126 occurs. The power semiconductor chip 101, which is a source of heat, is disposed at the ends and is disposed in plural, necessitating suppression of in-plane variation.

For example, when a length of the metal base 126 in a longitudinal direction is 130 mm and a difference in the clearances at the end and the center portion widens by 0.1 mmm or more, variation (ΔRth) of the thermal resistance Rth increases, and in a case of 0.2 mm, ΔRth increases about 10%.

As described, in the conventional semiconductor device, convex upward deformation occurs when the semiconductor module 150 is fastened to the water jacket 129, a difference in the clearance between the water jacket 129 and the heat dissipation fins 128 at the center portion and the clearance between the water jacket 129 and the heat dissipation fins 128 at the ends of the semiconductor module 150 occurs, resulting in a difference in cooling capability, whereby a problem arises in that variation in the thermal resistance of the metal base 126 occurs.

Embodiments of a semiconductor device and a method of manufacturing a semiconductor device according to the present disclosure are described in detail with reference to the accompanying drawings. However, the present disclosure is not limited by the embodiments described below.

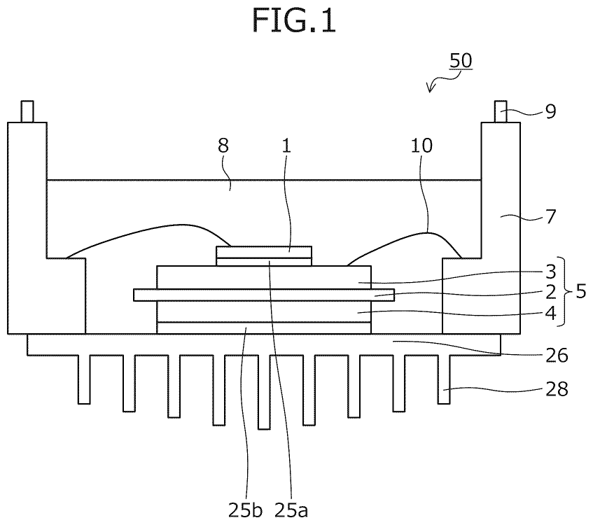

FIG. 1 is a cross-sectional view depicting a structure of a semiconductor module according to an embodiment. A semiconductor module 50 has a stacked substrate 5 in which a first conductive plate 3 containing copper is disposed at one surface of an insulating substrate 2 and a second conductive plate 4 containing, for example, copper is disposed at the other surface of the insulating substrate 2, the one surface constituting a front surface and the other surface constituting a back surface. On a front surface of the first conductive plate 3 of the stacked substrate 5, multiple power semiconductor chips 1 are mounted via a first bonding layer 25a constituted by, for example, solder. Metal terminals 9 that lead signals to an external destination are disposed so as to pass through an inside of a case 7 and be exposed in the case 7. Furthermore, conductive connecting members such as pin-type terminals, lead frames, etc. are attached to a front surface (for example, a source electrode pad) of each of the power semiconductor chips 1, via metal wires 10 (bonding wires) such as aluminum wires and a bonding layer (not depicted). Further, the power semiconductor chips 1 and the metal terminals 9 are electrically connected to each other by, for example, the metal wires 10 constituted by, for example, aluminum wires. Lead frames may be used (not depicted). A primer layer (not depicted) for improving adhesion may be stacked on members to be encapsulated such as the power semiconductor chips 1, the stacked substrate 5, the first bonding layer 25a, and the metal wires 10 (conductive connecting member). Further, the case 7 is filled with an encapsulating resin 8. The depicted configuration of the semiconductor module 50 is one example and the present invention is not limited to this configuration. Depending on the constituent members, the semiconductor module, in a top view thereof, may be a substantially rectangular shape or a substantially square shape, a substantially oblong rectangular shape being used most often. In an instance of a substantially oblong rectangular shape having long sides and short sides, the center portion may be a center portion in a direction parallel to the long sides or may be a center portion in a direction parallel to the short sides.

The power semiconductor chips 1 are power chips of, for example, a metal oxide semiconductor field effect transistor (MOSFET), an insulated gate bipolar transistor (IGBT), or a Schottky barrier diode (SBD) diode SBD, a device in which Si, SiC, or GaN is used in a semiconductor substrate may be used. In particular, the present disclosure is effective for SiC chips and GaN chips, which have high power and a high Young's modulus. The number of the power semiconductor chips 1 mounted may be one or more.

In each of the power semiconductor chips 1, an electrode (back electrode) of a back surface thereof is bonded to the first conductive plate 3 of the front surface of the stacked substrate 5 by the first bonding layer 25a constituted by solder or the like. The second conductive plate 4 of the back surface of the stacked substrate 5 is bonded to a front surface of a metal base 2 by a second bonding layer 25b constituted by solder or the like. The first conductive plate 3 is formed in a predetermined circuit pattern at the front surface (first main surface) of the insulating substrate 2. The second conductive plate 4 may be a metal foil formed in an entire area of the back surface of the insulating substrate 2.

The stacked substrate 5 may be configured by the insulating substrate 2, the first conductive plate 3 formed in a predetermined shape on one surface of the insulating substrate 2, and the second conductive plate 4 formed on the other surface of the insulating substrate 2. As the insulating substrate 2, a material with excellent electrical insulation and thermal conductivity may be used. A material of the insulating substrate 2 may be, for example, a ceramic such as Al₂O₃, AlN, or SiN. In particular, in high-voltage applications, while materials that have both electrical insulation and thermal conductivity are preferable and AlN and SiN may be used, the configuration is not limited hereto. Further, a resin insulating substrate made of an epoxy resin containing particles with high thermal conductivity such as boron nitride may be used. As the first conductive plate 3 and the second conductive plate 4, copper (Cu) or a Cu alloy having excellent workability may be used. A Cu alloy is an alloy containing 80% or more Cu. Among such conductive plates containing Cu or a Cu alloy, a conductive plate that is not in contact with the power semiconductor chips 1 (second conductive plate) is sometimes referred to as a back copper foil or a back conductive plate. Methods for disposing a conductive plate on the insulating substrate 2 include a direct copper bonding method and an active metal brazing method. Further, the surface of the conductive substrate may be plated with Ni (nickel) to form a Ni or Ni alloy layer.

The metal base 26 is a heat sink having, for example, a substantially rectangular shape in a plan view and containing a metal such as Cu or Al, which have excellent thermal conductivity; the metal base 26 is also referred to as a metal substrate. A surface of the metal base 26 may be covered with a Ni film or an Ni alloy film, which have an effect of preventing corrosion. At a back surface of the metal base 26, multiple the heat dissipation fins 28 are provided. The metal base 26 conducts, to the heat dissipation fins 28, heat that is generated in the power semiconductor chips 1 and transferred through the stacked substrate 5. The heat dissipation fins 28 dissipate the heat conducted from the metal base 26. A cooling device (the metal base 26) having the heat dissipation fins 28 may be attached to a plate-shaped metal base.

The first bonding layer 25a and the second bonding layer 25b may be formed using a lead-free solder. Without limitation hereto, for example, Sn—Sb, Sn—Cu, Sn—Ag, Sn—Sb—Ag, etc. based alloys may be used. A sintering material using nano-metal particles such as silver or copper may also be used. Further, materials and composition of the first bonding layer 25a between the first conductive plate of the stacked substrate and a semiconductor device element may differ from materials and composition of the second bonding layer 25b between the second conductive plate and the metal base.

A lower end of the case 7, which contains a resin or the like, is adhered to a periphery of the metal base 2. The case 7 forms a substantially rectangular tubular shape and surrounds the periphery of the front surface of the metal base 26 in a plan view. A box-shaped recess is formed in which the front surface of the metal base 26 is assumed as a floor of the box shape and inner walls of the case 7 orthogonal to the front surface of the metal base 26 are assumed as sidewalls of the box shape. In the recess, the stacked substrate 5 and the power semiconductor chips 1 connected to wiring members such as a lead frame and the metal wires 10, and wiring member components are housed. A material of the case 7 may be, for example, a thermoplastic resin such as polyphenylene sulfide (PPS) and polybutylene terephthalate (PBT) or a thermosetting resin such as a phenolic resin. The power semiconductor chips 1 and the stacked substrate 5 may be molded with the encapsulating resin 8 to form the semiconductor module 50 without including the case.

The primer layer (not depicted) may be formed on the members that are to be encapsulated. The primer layer may be a layer consisting of a resin containing polyamide, polyimide, or polyamideimide. The primer layer may be advantageously used since the primer layer can improve the adhesion at the interface between the conductive connecting members such as the metal wires 10 or the lead frame, the stacked substrate 5 (particularly the first conductive plate 3 on the main surface side), the metal base 26, the case 7 (inner surface), and the sealing resin 8, and can relieve stress. The semiconductor module 50 may be free of the primer layer.

The encapsulating resin 8 is used as an encapsulating resin layer that encapsulates the members that are to be encapsulated, and is provided in contact with the primer layer, or in a semiconductor module that does not have the primer layer, is provided in contact with the members that are to be encapsulated, and mainly covers the periphery of the power semiconductor chips 1, the stacked substrate 5, the metal wires 10, the lead frame, etc. The encapsulating resin 8 may be composed of a thermosetting resin composition and in particular, preferably, may be composed of a thermosetting resin composition having high heat resistance. The thermosetting resin composition contains a thermosetting resin base, and may optionally contain an inorganic filler, a curing agent, a curing accelerator, and necessary additives. While the thermosetting resin composition that constitutes the encapsulating resin 8 may or may not contain a fluorine-based silane coupling agent, it is preferable that the thermosetting resin composition does not contain one, as this may lower the glass transition temperature (Tg) of the encapsulating resin 8.

While not particularly limited, the thermosetting resin base may be, for example, an epoxy resin, a phenolic resin, a maleimide resin or the like. Among these, epoxy resins with at least two epoxy groups per molecule are particularly preferred because these resins have high dimensional stability, water resistance, chemical resistance, and electrical insulation. Specifically, it is preferable to use an aliphatic epoxy resin, an alicyclic epoxy resin, or a combination thereof. In an instance in which the case is included, the encapsulating resin layer may be a silicone compound such as a silicone gel.

An aliphatic epoxy resin is an epoxy compound in which the carbon to which the epoxy group is directly bonded constitutes an aliphatic hydrocarbon. Thus, even when a compound contains an aromatic ring in the main skeletal structure, if the compound meets the above conditions, the compound is classified as an aliphatic epoxy resin. Aliphatic epoxy resins include, but are not limited to, bisphenol A type epoxy resins, bisphenol F type epoxy resins, bisphenol AD type epoxy resins, biphenyl type epoxy resins, naphthalene type epoxy resins, cresol novolac type epoxy resins, and multifunctional epoxy resins with three or more functional groups. These may be used alone or in a combination of two or more. Further, naphthalene-type epoxy resins and trifunctional or higher multifunctional epoxy resins have a high glass transition temperature and thus, are also called high heat-resistant epoxy resins. Inclusion of these high heat-resistant epoxy resins may improve heat resistance.

Alicyclic epoxy resin refers to an epoxy compound in which the two carbon atoms that make up the epoxy group form an alicyclic compound. Alicyclic epoxy resins include, but are not limited to, monofunctional epoxy resins, bifunctional epoxy resins, and trifunctional and higher multifunctional epoxy resins. Alicyclic epoxy resins may also be used alone or in a combination with two or more different alicyclic epoxy resins. In addition, when an alicyclic epoxy resin is mixed with an acid anhydride curing agent and cured, the glass transition temperature increases and thus, mixing an alicyclic epoxy resin with an aliphatic epoxy resin may improve heat resistance.

The thermosetting resin base agent used in the composition according to the present embodiment may be a mixture of the above-mentioned aliphatic epoxy resin and alicyclic epoxy resin. A mixing ratio may be arbitrary; a mass ratio of the aliphatic epoxy resin to the alicyclic epoxy resin may be about 2:8 to 8:2 or may be about 3:7 to 7:3 and is not limited to a specific mass ratio. Preferably, the thermosetting resin base agent may have a mass ratio of bisphenol A-type epoxy resin to alicyclic epoxy resin in a range of 1:1 to 1:4.

The thermosetting resin composition according to the present embodiment may contain an inorganic filler (filler) as an optional component. The inorganic filler may be a metal oxide or a metal nitride such as but not limited to, for example, fused silica (fused silicon oxide), silica (silicon oxide), alumina (aluminum oxide), aluminum hydroxide, titania (titanium dioxide), zirconia (zirconium oxide), aluminum nitride, talc, clay, mica, glass fibers, and the like. These inorganic fillers may increase the thermal conductivity of the cured material and reduce the thermal expansion rate. Further, these inorganic fillers may be used alone or in a combination of two or more. Furthermore, these inorganic fillers may be microfillers or nanofillers, and two or more types of inorganic fillers of different particle sizes and/or types may be used in combination.

The thermosetting resin composition may contain, as an optional component, a curing agent in addition to the thermosetting resin base agent, or in addition to the thermosetting resin base agent and the inorganic filler. While the curing agent is not particularly limited as long as the curing agent reacts with the thermosetting resin base agent (preferably an epoxy resin base agent) and can be cured, preferably, an acid anhydride curing agent may be used. Examples of acid anhydride curing agents include aromatic acid anhydrides, specifically phthalic anhydride, pyromellitic anhydride, trimellitic anhydride, and the like. Alternative examples include cycloaliphatic acid anhydrides, specifically tetrahydrophthalic anhydride, methyltetrahydrophthalic anhydride, hexahydrophthalic anhydride, methylhexahydrophthalic anhydride, methylnadic anhydride, etc., or aliphatic acid anhydrides, specifically succinic anhydride, polyadipic anhydride, polysebacic anhydride, polyazelaic anhydride, and the like. In addition, when a bisphenol A type epoxy resin is used alone or a mixture of a bisphenol A type epoxy resin and the previously mentioned high heat-resistant epoxy resin is used as a thermosetting resin base agent, it may be preferable not to use a curing agent because heat resistance is improved.

The thermosetting resin composition may further optionally contain, as an optional component, a curing accelerator. As the curing accelerator, imidazole or its derivatives, tertiary amines, boric acid esters, Lewis acids, organometallic compounds, organic acid metal salts, or the like may be suitably added.

The thermosetting resin composition may further contain optional additives, provided the additives do not impair the properties of the thermosetting resin composition. Examples of additives include, but are not limited to, flame retardants, pigments to color resins, plasticizers and silicone elastomers to improve crack resistance. These optional components and the added amount thereof may be suitably determined according the specifications necessary for the semiconductor module and/or encapsulant by one skilled in the art.

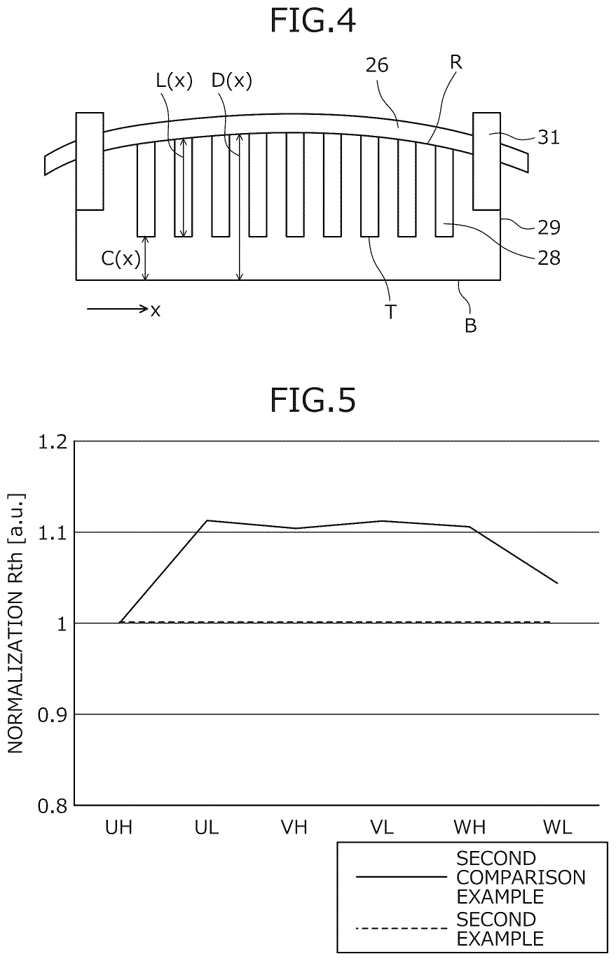

The heat dissipation fins 28 provided on the metal base 26 are disposed so as to be housed in a water jacket 29 and are provided from a vicinity of sidewalls of the water jacket 29 (both end sides of the metal base 26) to a center portion of the water jacket 29 (center portion of the metal base 26). Further, the heat dissipation fins 28 may be disposed substantially orthogonally from a back surface R of the metal base 26 in a direction to a floor B of the water jacket 29 or may be disposed having an incline. In the semiconductor module 50 of the embodiment, corresponding to warpage of the metal base 26, lengths of the heat dissipation fins 28 at both ends differ from lengths thereof in the center portion, the lengths being longer in the center portion. Similar to a conventional case, the semiconductor module 50 is warped before the water jacket 29 is fastened and is in a convex downward state. The heat dissipation fins 28 of the center portion are longer by an amount corresponding to the warpage. The lengths of the heat dissipation fins 28 of the metal base 26 are adjusted in the center portion and at both ends, whereby gaps (clearance) between tips T of the heat dissipation fins 28 and the floor B of the water jacket 29 are constant in the semiconductor module 50 after the water jacket 29 is fastened (refer to FIG. 4), regardless of the locations where the power semiconductor chips 1 of the semiconductor module 50 are disposed. The closer is a heat dissipation fin 28 to the center of the metal base 26, the longer is the length thereof and the lengths of some of the heat dissipation fins 28 at each end of the metal base 26 (for example, of the heat dissipation fins 28, a closest one to an end of the metal base 26 and a second closest one adjacent to the closest one and closer to the center portion) may be substantially the same so that the clearance is within a constant range. The floor B of the water jacket 29 is the inner surface of the bottom plate thereof, facing the heat dissipation fins 28; and the back surface R of the metal base 26 is the surface thereof facing the floor B of the water jacket 29. Further, the length of each of the heat dissipation fins is a distance in a z-direction, from the back surface R of the metal base to the tip of the heat dissipation fin. The z-direction is a direction orthogonal to the back surface R of the metal base or the floor B of the water jacket.

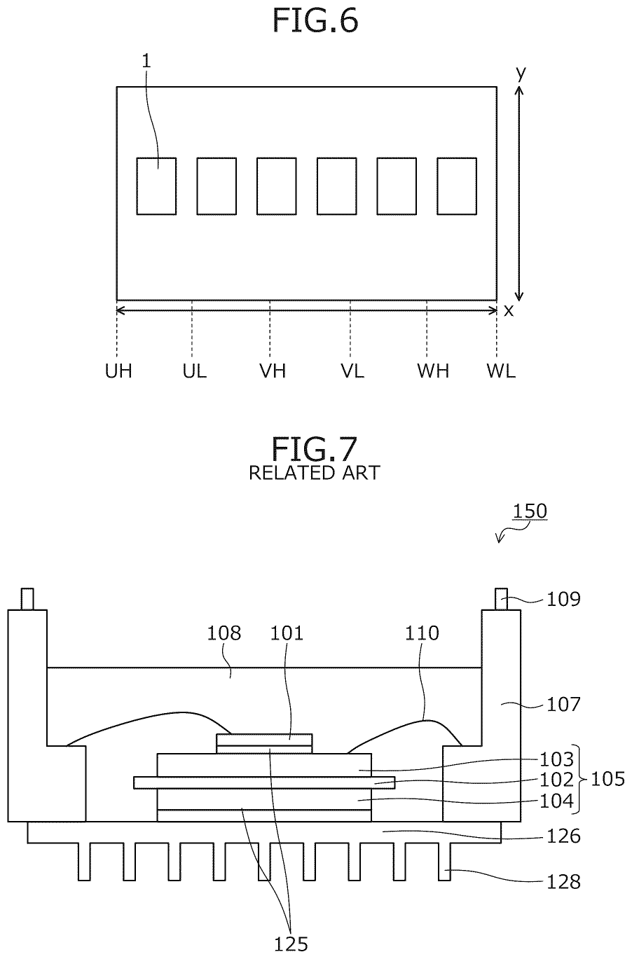

The heat dissipation fins 28 may be, for example, plate-like, prismatic, round, or triangular in shape. The heat dissipation fins 28 may also be flat, thin, ribbon-like fins or fins with an embossed surface. In an instance of a plate-like shape, the heat dissipation fins 28 may be disposed parallel to a lateral direction (a y-direction) depicted in FIG. 6.

The water jacket 29 is provided so as to cover the heat dissipation fins 28 of the metal base 26. The water jacket 29 has an inlet (not depicted) and an outlet (not depicted) for the cooling medium; the inlet and the outlet, for example, may be provided at the sidewalls at the ends in the x-direction in FIG. 4 or may be provided at the ends in the y-direction (refer to FIG. 6), which is orthogonal to the x-direction. Further, the inlet and the outlet may be offset. The cooling medium flows between the metal base 26 and the water jacket 29. As described, the semiconductor module 50 and the water jacket 29 are fastened to each other, forming the semiconductor device.

The water jacket 29 has the flat bottom plate, the sidewalls, and a flange-shaped fastener. The bottom plate, the sidewalls, and the fastener may be integrally molded by press processing, etc., or may be connected by welding or the like. The bottom plate, the sidewalls, and the fastener, for example, may be configured by a metal material such as iron or aluminum. The water jacket 29 further has fastening members fastening the metal base 26 and the fastener. While the fastening members are, for example, fastening screws 31, other fastening members may be used. The water jacket 29 has a sealing member that seals the cooling medium, such as an O-ring 30 or gasket on an inner side of the fastening members. The metal base 26, the water jacket 29, and the heat dissipation fins 28 may be referred to as a cooling device.

Further, preferably, the floor B of the bottom plate of the water jacket 29 may be flat. For example, preferably, the floor B has a flatness of 0.1 mm or less. When the bottom plate warps, the flow of the cooling medium becomes uneven in a vicinity of the floor B of the bottom plate of the water jacket 29. Further, when the semiconductor device having the cooling device is disposed in an automobile or a control device, the floor B of the water jacket 29 has to be flat for installation stability. Further, to maintain a constant clearance, it is difficult to manufacture the heat dissipation fins 28 with a constant length and to deform the bottom plate to provide a predetermined warpage.

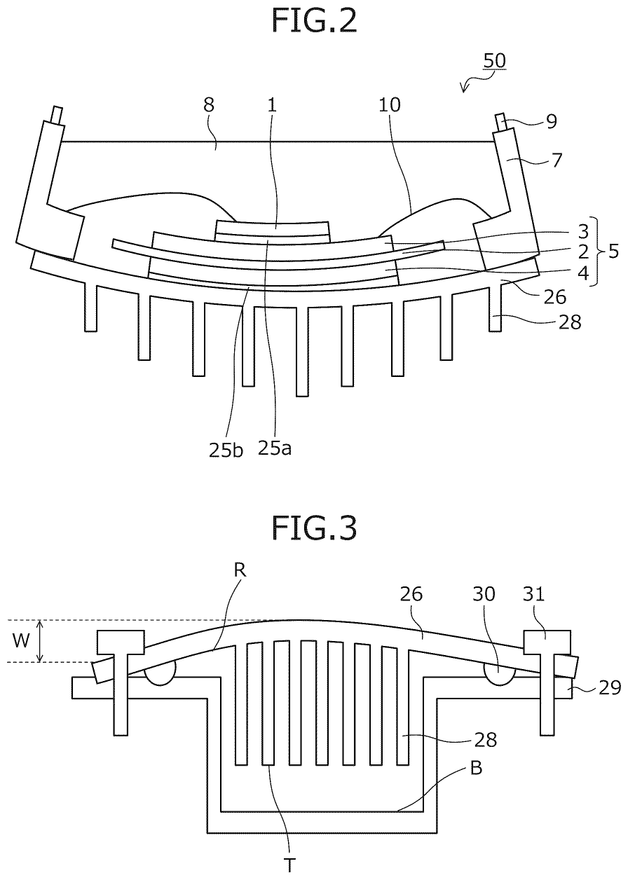

FIG. 2 is a cross-sectional view depicting a warped state of the semiconductor module according to the embodiment. Similar to a conventional case, in the semiconductor module 50 according to the embodiment, when a bonding process such as soldering with a heat treatment is performed on the metal base 26 and the stacked substrate 5 to which the power semiconductor chips 1, the metal wires 10, etc. are mounted, due to the linear expansion coefficients being different, the stacked substrate 5 warps together with the metal base 26 and the semiconductor module 50 also warps, resulting in a convex downward (direction opposite to direction of the power semiconductor chips 1) state.

Similar to a conventional case, the semiconductor device according to the embodiment is fastened by the fastening screws 31, via a sealing member such as a gasket or the O-ring 30 between the semiconductor module 50 and the water jacket 29. Since the water jacket 29 is fastened at four locations, the center portion of the semiconductor module 50 becomes deformed in a convex upward (direction to the power semiconductor chips 1) shape due to the reaction force and internal pressure of the gasket or the O-ring 30. As described, warpage is not corrected even when the warped semiconductor module 50 is fastened to the water jacket 29 but rather occurs in the reverse direction. In the embodiment, for example, the metal base 26 becomes convex upward when the amount of warpage W (displacement) is 0.1 mm or more. The amount of warpage is a difference in the height of the center portion of the metal base 26 and the height of the ends of the metal base 26.

FIG. 3 is a cross-sectional view depicting a state after fastening of the water jacket of the semiconductor device according to the embodiment. As depicted in FIG. 3, while the center portion of the semiconductor module 50 is in a convex upward state (the metal base 26 is also convex upward), the lengths of the heat dissipation fins 28 of the metal base 26 are adjusted in the center portion and at both ends, whereby differences in the gaps (clearance) between the tips T of the heat dissipation fins 28 and the floor B of the water jacket 29 become constant. In FIGS. 3 and 4, the semiconductor chip, the stacked substrate, etc. are not depicted.

In particular, the heat dissipation fins 28 are formed to be in ascending order length, from the ends of the metal base 26 to the center portion. For example, as depicted in FIG. 4, when the semiconductor module 50 is warped convex upward along the x-direction (longitudinal direction), the heat dissipation fins 28 are in ascending order of length, from one end in the x-direction (longitudinal direction) to the center portion and are in descending order, from the center portion to the other end. Further, in an instance in which the semiconductor module 50 and the metal base 26 are warped convex upward along the y-direction (lateral direction), the heat dissipation fins 28 may be in ascending order of length, from an end in the y-direction (lateral direction) to the center portion and may be in descending order of length, from the center portion to the other end. Configuration is similar in an instance of warpage in both the x-direction (longitudinal direction) and the y-direction (lateral direction). The clearance difference≈the amount of warpage W≈maximum warpage and therefore, in particular, the lengths of the heat dissipation fins 28 are such that distances from the floor of the water jacket 29 to the tips of the heat dissipation fins 28 are constant so that the difference in clearance decreases. The metal base 26 is assumed to be a sum of a length corresponding to the amount of warpage W (displacement) and the length of the heat dissipation fins 28. Thus, the clearance is constant regardless of the locations where the power semiconductor chips 1 of the semiconductor module 50 are disposed. As a result, no difference in the cooling capability by the heat dissipation fins 28 and the water jacket 29 at the center portion and at the ends of the semiconductor module 50 occurs and thus, without variation of the thermal resistance, reliability of the semiconductor device may be improved.

As described, in the embodiment, the shapes (lengths) of the heat dissipation fins 28 are changed and thus, the flow of the cooling medium is changed and flow paths are efficient, whereby fundamental thermal resistance may be reduced. The lengths of the heat dissipation fins 28 at locations where the thermal resistance varies are changed, whereby it becomes possible to adjust to a smallest thermal resistance value. In other words, variation of the thermal resistance may be suppressed.

FIG. 4 is an enlarged view of a cross-section of the heat dissipation fins of the semiconductor device according to the embodiment in a state after fastening of the water jacket. As depicted in FIG. 3, while the metal base 26 and the water jacket 29 are fastened by the fastening screws 31, this is not depicted in FIG. 4. In FIG. 4, C(x) is the clearance at position x, that is, the gap between the floor B of the water jacket 29 and the tip T of the heat dissipation fin 28 at position x. Position x represents a distance from one end of the semiconductor module 50 and is 0 at the one end. L(x) is the length of the heat dissipation fin 28 at position x and D(x) is the distance between the back surface R of the metal base 26 and the floor B of the water jacket 29 at position x.

In the embodiment, as a specific method of setting the lengths of the heat dissipation fins 28 according to warpage, (1) in a method of measuring D(x), the length L(x) of each of the heat dissipation fins 28 is determined so that when assuming a clearance CL, D(x)−L(x)=CL (within a certain value). In other words, L(x)=D(x)−CL. (2) In a method of measuring C(x), when assuming L(0) to be the length (end) of a reference one of the heat dissipation fins 28, so that the length L(x) of each of the heat dissipation fins 28 is determined so that L(x)=L(0)+(C(x)−C(0)). As described below, D(x) and C(x) may be obtained by making a slit in the bottom of the water jacket 29 and from there, measuring the distance from the floor B of the water jacket 29 to the back surface R of the metal base 26 or the tip T of the heat dissipation fin 28 using an optical distance sensor (laser distance measuring instrument). C(0) represents the distance from the floor of the water jacket 29 for testing to the tip of a closest one of the heat dissipation fins 28, the closest one being closest to an end, of the heat dissipation fins 28.

Next, whether variation in the thermal resistance occurs when the semiconductor module 50 warps a certain extent was confirmed by experimental examples. Table 1 shows results of the experimental examples. In the experimental examples, an instance was confirmed in which the longitudinal length of the water jacket 29 was 130 mm (first to fifth experimental examples), 65 mm (sixth and seventh experimental examples), and 200 mm (eighth and ninth experimental examples). An instance was tested in which the amount of warpage W of the metal base 26 was in a range of 0 mm to 0.5 mm and a specified clearance (length of gap between the floor of the water jacket 29 and the tip of the heat dissipation fin 28 when the amount of warpage W was 0 mm) was 0.5 mm. The maximum clearance is a sum of the amount of warpage W and the specified clearance, and the lengths of the heat dissipation fins 28 are not adjusted and thus, the clearance difference is the same as the amount of warpage W.

TABLE 1

| | FIRST | SECOND | THIRD | FOURTH | FIFTH |
|---|---|---|---|---|---|
| | EXPERIMENTAL | EXPERIMENTAL | EXPERIMENTAL | EXPERIMENTAL | EXPERIMENTAL |
| | EXAMPLE | EXAMPLE | EXAMPLE | EXAMPLE | EXAMPLE |
| WJ SIZE, | 130 | 130 | 130 | 130 | 130 |
| LONGITUDINAL LENGTH | | | | | |
| COOLING FIN LENGTH | 6 | 6 | 6 | 6 | 6 |
| METAL BASE WARPAGE | 0.5 | 0.2 | 0.1 | 0.05 | 0 |
| (MAXIMUM AMOUNT: | | | | | |
| CENTER PORTION) | | | | | |
| SPECIFIED CLEARANCE | 0.5 | 0.5 | 0.5 | 0.5 | 0.5 |
| MAXIMUM CLEARANCE | 1.0 | 0.7 | 0.6 | 0.55 | 0.5 |
| CLEARANCE DIFFERENCE | 0.5 | 0.2 | 0.1 | 0.05 | 0 |
| (≈WARPAGE AMOUNT W) | | | | | |
| MAXIMUM COOLING FIN LENGTH | NONE | NONE | NONE | NONE | NONE |
| ADJUSTMENT | | | | | |
| MAXIMUM THERMAL | 1.2 | 1.1 | 1.06 | 1 | 1 |
| RESISTANCE VARIATION | | | | | |
| (CENTER PORTION Rth/END Rth) | | | | | |

| | SIXTH | SEVENTH | EIGHTH | NINETH |
|---|---|---|---|---|
| | EXPERIMENTAL | EXPERIMENTAL | EXPERIMENTAL | EXPERIMENTAL |
| | EXAMPLE | EXAMPLE | EXAMPLE | EXAMPLE |
| WJ SIZE, | 65 | 65 | 200 | 200 |
| LONGITUDINAL LENGTH | | | | |
| COOLING FIN LENGTH | 6 | 6 | 6 | 6 |
| METAL BASE WARPAGE | 0.1 | 0.05 | 0.1 | 0.05 |
| (MAXIMUM AMOUNT: | | | | |
| CENTER PORTION) | | | | |
| SPECIFIED CLEARANCE | 0.5 | 0.5 | 0.5 | 0.5 |
| MAXIMUM CLEARANCE | 0.6 | 0.55 | 0.6 | 0.55 |
| CLEARANCE DIFFERENCE | 0.1 | 0.05 | 0.1 | 0.05 |
| (≈WARPAGE AMOUNT W) | | | | |
| MAXIMUM COOLING FIN LENGTH | NONE | NONE | NONE | NONE |
| ADJUSTMENT | | | | |
| MAXIMUM THERMAL | 1.15 | 1 | 1.05 | 1 |
| RESISTANCE VARIATION | | | | |
| (CENTER PORTION Rth/END Rth) | | | | |

As depicted in Table 1, when the amount of warpage W of the metal base 26 in a region of the heat dissipation fins 28 is 0.1 mm or more, the maximum thermal resistance variation (center portion Rth/end Rth) increases. For example, when the second experimental example and the fifth experimental example are compared, the maximum thermal resistance variation increases by 10% when the amount of warpage W (clearance difference) is 0.2 mm or more. Even when the size of the semiconductor module 50 (size of the water jacket 29) is different, the results are the same.

Next, results of correcting the lengths of the heat dissipation fins 28 in an instance in which the amount of warpage W of the metal base 26 was 0.1 mm or more were confirmed. Table 2 show results of comparison examples and the examples. The comparison examples are the same as the experimental examples in Table 1 and are instances in which the lengths of the heat dissipation fins 28 are not corrected while the examples are instances in which the lengths of the heat dissipation fins 28 are corrected. In the comparison examples and the examples, instances in which the longitudinal length of the water jacket 29 was 130 mm (the first to third comparison examples, the first to sixth examples), 65 mm (the fourth comparison example, the seventh example) were confirmed. Experiments were performed with the amount of warpage W of the metal base 26 being in a range of 0.1 mm to 0.5 mm and the specified clearance being 0.5 mm. In the comparison examples in which the maximum clearance was a sum of the amount of warpage W and the specified clearance and the lengths of the heat dissipation fins 28 were not adjusted, the clearance difference was the same as the amount of warpage W. In the examples in which the lengths of the heat dissipation fins 28 were adjusted, the clearance difference was an adjustment value obtained as the amount of warpage W—the length of the heat dissipation fin 28.

Further, power cycle (P/C) tests of semiconductor devices having heat dissipation fins of differing conditions were performed and the reliability of the comparison examples and the examples was confirmed. The P/C tests were performed with energization so that a temperature was in a range of 40 degrees C. to 175 degrees C. with one cycle consisting of 2 seconds of energized operation and 9 seconds of rest, and the number of cycles until no abnormality in electrical properties occurred due to the progression of cracks on the resin surface was recorded. Instances in which the number of cycles was less than 10 k were evaluated as not good (NG) while instances in which the number of cycles was 10 k or more were evaluated as OK.

TABLE 2

| | FIRST | | SECOND | | | |
|---|---|---|---|---|---|---|
| | COMPARISON | | COMPARISON | | | |
| | EXAMPLE | | EXAMPLE | | | |
| | FIRST | | SECOND | | | |
| | EXPERIMENTAL | FIRST | EXPERIMENTAL | SECOND | THIRD | FOURTH |
| | EXAMPLE | EXAMPLE | EXAMPLE | EXAMPLE | EXAMPLE | EXAMPLE |
| WJ SIZE, | 130 | 130 | 130 | 130 | 130 | 130 |
| LONGITUDINAL LENGTH | | | | | | |
| COOLING FIN LENGTH | 6 | 6 | 6 | 6 | 6 | 6 |
| METAL BASE WARPAGE OF MODULE | 0.5 | 0.5 | 0.2 | 0.2 | 0.2 | 0.1 |
| (MAXIMUM AMOUNT: CENTER | | | | | | |
| PORTION) | | | | | | |
| SPECIFIED CLEARANCE | 0.5 | 0.5 | 0.5 | 0.5 | 0.5 | 0.5 |
| MAXIMUM CLEARANCE | 1.0 | 0.5 | 0.7 | 0.7 | 0.6 | 0.5 |
| MAXIMUM COOLING FIN LENGTH | NONE | 0.5 | NONE | 0.2 | 0.1 | 0.1 |
| ADJUSTMENT | | | | | | |
| CLEARANCE DIFFERENCE | 0.5 | 0.0 | 0.2 | 0.0 | 0.1 | 0 |
| (≈WARPAGE AMOUNT W) | | | | | | |
| MAXIMUM THERMAL RESISTANCE | 1.2 | 1 | 1.1 | 1 | 1.06 | 1 |
| VARIATION (CENTER PORTION Rth/ | | | | | | |
| END Rth) | | | | | | |
| RELIABILITY (P/C TEST) | NG | OK | NG | OK | OK | OK |

| | | THRI D | | FOURTH | |
|---|---|---|---|---|---|
| | FIFTH | COMPARISON | SIXTH | COMPARISON | SEVENTH |
| | EXAMPLE | EXAMPLE | EXAMPLE | EXAMPLE | EXAMPLE |
| WJ SIZE, | 130 | 130 | 130 | 65 | 65 |
| LONGITUDINAL LENGTH | | | | | |
| COOLING FIN LENGTH | 6 | 6 | 6 | 6 | 6 |
| METAL BASE WARPAGE OF MODULE | 0.1 | 0.2 | 0.2 | 0.2 | 0.2 |
| (MAXIMUM AMOUNT: CENTER | | | | | |
| PORTION) | | | | | |
| SPECIFIED CLEARANCE | 0.5 | 0.25 | 0.25 | 0.5 | 0.5 |
| MAXIMUM CLEARANCE | 0.55 | 0.45 | 0.25 | 0.7 | 0.5 |
| MAXIMUM COOLING FIN LENGTH | 0.05 | NONE | 0.2 | NONE | 0.2 |
| ADJUSTMENT | | | | | |
| CLEARANCE DIFFERENCE | 0.05 | 0.2 | 0.0 | 0.2 | 0.0 |
| (≈WARPAGE AMOUNT W) | | | | | |
| MAXIMUM THERMAL RESISTANCE | 1.0 | 1.1 | 1 | 1.12 | 1 |
| VARIATION (CENTER PORTION Rth/ | | | | | |
| END Rth) | | | | | |
| RELIABILITY (P/C TEST) | OK | NG | OK | NG | OK |

FIG. 5 is a graph depicting variation evaluation of thermal resistance of the metal base according to the embodiment. FIG. 6 is a top view depicting thermal resistance variation measurement positions of the metal base according to the embodiment. In FIG. 5, a horizontal axis represents thermal resistance variation measurement positions. UH, UL, VH, VL, WH, WL are positions of the power semiconductor chips 1 depicted in FIG. 6. A vertical axis represents normalized thermal resistance with the thermal resistance (K/W) at a UH position assumed to be 1.

FIG. 5 shows results of the second comparison example (solid line) and the second example (dotted line) in Table 2. The longitudinal length of the water jacket 29 was 130 mm, the amount of warpage W of the metal base 26 was 0.2 mm, and the specified clearance was 0.5 mm. With water flowing, the thermal resistance (Rth) was calculated from the temperature of the power semiconductor chips 1 and the temperature of the back surface of the metal base 26, at measurement points for power consumption during energization. As a result, it was found that variation of the thermal resistance was 10% or more in VH, VL, etc. of the center portion, which has a large clearance.

As depicted in Table 2, when the maximum thermal resistance variation is 1.1 (10%) or more, this was found to be undesirable because a temperature gradient occurs in the module and thermal stress causes peeling to easily occur at the interface of the encapsulating resin 8 and the stacked substrate 5, the power semiconductor chips 1, etc. thereby, reducing reliability of the P/C (power cycling test), etc. Thus, preferably, the maximum thermal resistance variation may be set to less than 1.1.

When the thermal resistance of the metal base 26 increases, the heat generated in (temperature of) the power semiconductor chips 1 increases during driving. As a result, the reliability of the semiconductor device decreases, the temperature gradient between the power semiconductor chips 1 and the metal base 26 increases, characteristics of the semiconductor device degrade (destruction of device element bonding), and degradation of bonding materials progresses, causing P/C tolerance to decrease. Furthermore, when the thermal resistance varies, the life of the semiconductor device becomes shorter, and the reliability decreases. In this instance, operation has to be performed lowering the current value of the power semiconductor chips 1 and lowering the performance. Decrease in the P/C tolerance is remarkable when the maximum thermal resistance variation exceeds 10% and has to be less than 10%.

Therefore, in the embodiment, when the clearance difference (difference of maximum clearance C(x) and minimum clearance C(x)) is less than 0.2 mm, the maximum thermal resistance variation may be suppressed to 1.1 or less (10% or less) and thus, is desirable. Furthermore, when the clearance difference is 0.1 mm or less, the maximum thermal resistance variation may be suppressed to 1.06 (6%) and thus, is preferable.

Next, a method of manufacturing a semiconductor device according to the embodiment is described. First, the warpage of the metal base 26 is measured. To measure the warpage of the metal base 26, a test module with the same components and size as the actual semiconductor device is prepared. A semiconductor device is prepared in which the water jacket 29 for testing is fastened to a joint body in which the metal base 26 having the heat dissipation fins 28 and an encapsulating body are bonded (in the encapsulated body, the stacked substrate 5 to which the power semiconductor chips 1, wiring members, etc. are mounted, is encapsulated by the encapsulating resin 8).

Next, slits are provided at predetermined positions x at the bottom of the water jacket 29 for testing and from there, the clearance C(x), which is the distance from the floor B of the water jacket 29 to the tips T of the heat dissipation fin 28 having uniform lengths is measured (clearance measurement) using an optical distance sensor (laser distance measuring instrument).

Next, the metal base 26 having the heat dissipation fins 28 of lengths adjusted according to the amount of warpage of the metal base 26 is formed. For example, the metal base 26 having the heat dissipation fins 28 of a uniform length is prepared and the length L(x) of each of the heat dissipation fins 28 at each position is adjusted by machine processing to be a sum of the length L(0) of the closest one of the heat dissipation fins 28 to one end and a difference of the distances C(x) and C(0) from the floor of the water jacket 29 for testing, to the tips of the respective heat dissipation fins (L(x)=L(0)+ (C(x)−C(0))). Here, C(0) represents the distance from the floor of the water jacket 29 for testing, to the tip of the closest one of the heat dissipation fins 28 to the one end. Further, D(x) may be used.

As described, after the amount of warpage of the metal base 26 is measured, the power semiconductor chips 1 are bonded to the stacked substrate 5 by the first bonding layer 25a thereby fabricating a stacked body in which the power semiconductor chips 1, wiring members such as the metal wires 10, and the stacked substrate 5 are bonded. Thereafter, the metal base 26 in which the lengths of the heat dissipation fins 28 are adjusted is bonded to the stacked substrate 5 by the second bonding layer 25b and after the case 7 is attached to the metal base 26, bonding of a lead frame and wire bonding by the metal wires 10 is performed. Instead of a lead frame, the metal wires 10 may be used. Next, the primer layer may be formed. Thereafter, the stacked substrate 5 on which the power semiconductor chips 1, the wiring members, etc. are mounted is encapsulated with the encapsulating resin 8. A state resulting from the processes up to here is depicted in FIG. 2.

Next, the metal base 26 is fastened by the fastening screws 31 via a sealing member such as the O-ring 30 or a gasket between the metal base 26 and the water jacket 29. The water jacket is fastened at four locations by the screws. A state resulting from the processes up to here is depicted in FIG. 3 and the semiconductor device is manufactured.

Further, as a method of setting the length of the heat dissipation fins 28 according to the warpage, a method of measuring D(x) may be performed. In this instance, slits are provided at the bottom of the water jacket 29 for testing and from there, D(x), which is the distance from the floor B of the water jacket 29 to the back surface R of the metal base 26 is measured using an optical distance sensor (laser distance measuring instrument).

As described, according to the embodiment, the heat dissipation fins are formed to be in ascending order of length from the ends of the metal base to the center portion. As a result, the clearance is constant regardless of the locations where the power semiconductor chips of the semiconductor module are disposed. As a result, no difference in the cooling capability by the heat dissipation fins and the water jacket at the center portion and at the ends of the semiconductor module occurs and thus, without variation of the thermal resistance, reliability of the semiconductor device may be improved.

In the foregoing, the present invention may be variously modified within a range not departing from the spirit of the invention and in the embodiments described above, for example, dimensions, dopant concentrations, etc. of regions are variously set according to necessary specifications. Further, in the embodiment above, in addition to silicon as a semiconductor, application to a wide band gap semiconductor such as silicon carbide (SiC), gallium nitride (GaN), and the like is possible.

According to the disclosure, regardless of the locations where power semiconductor chips of a semiconductor device are disposed, clearance is constant. As a result, no difference in the cooling capability by the heat dissipation fins and the water jacket at the center portion and at the ends of the semiconductor module occurs and thus, without variation of the thermal resistance, reliability of the semiconductor device may be improved.

The semiconductor device and the method of manufacturing a semiconductor device according to the present disclosure achieve an effect in that the clearance between the heat dissipation fins and the water jacket is made constant, whereby differences in the cooling capability decrease and variation of the thermal resistance may be suppressed.

As described, the semiconductor device and the method of manufacturing a semiconductor device according to the present invention are useful for semiconductor modules used in power converting equipment such as inverters, power source devices of various types of industrial machines, automotive igniters, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a stacked substrate;
a semiconductor device element mounted on the stacked substrate via a first bonding layer;
a metal base bonded to the stacked substrate via a second bonding layer, the metal base having two ends and a center portion; and
a water jacket bonded to the metal base, wherein
the first and second bonding layers are identical, or different, in a material and a composition thereof; and
the metal base has a plurality of heat dissipation fins, lengths of which are in an ascending order from each of the ends to the center portion of the metal base.

2. The semiconductor device according to claim 1, wherein the metal base is convex upward towards the semiconductor device element.

3. The semiconductor device according to claim 2, wherein an amount of warpage of the metal base is 0.1 mm or more.

4. The semiconductor device according to claim 1, wherein a clearance between a floor of the water jacket and a tip of each of the plurality of heat dissipation fins is less than 0.2 mm.

5. The semiconductor device according to claim 1, wherein a clearance between a floor of the water jacket and a tip of each of the plurality of heat dissipation fins is less than 0.1 mm.

6. The semiconductor device according to claim 1, wherein a maximum thermal resistance variation of the metal base is not more than 1.1.

7. The semiconductor device according to claim 1, wherein a maximum thermal resistance variation of the metal base is not more than 1.06.

8. A method of manufacturing a semiconductor device, the method comprising:
mounting a semiconductor device element on a stacked substrate via a first bonding layer;
providing a metal base having a plurality of heat dissipation fins, measuring an amount of warpage of the metal base, and adjusting lengths of the plurality of heat dissipation fins according to the amount of warpage, so that the lengths of the plurality of heat dissipation fins are in an ascending order from each end of the metal base to a center portion thereof;
bonding the metal base to the stacked substrate via a second bonding layer; and
bonding a water jacket to the metal base, wherein
the first and second bonding layers are identical, or different, in a material and a composition thereof.

9. The method according to claim 8, wherein the adjusting includes:
bonding a test water jacket to the metal base,
measuring a distance from a floor of the test water jacket to a tip of each of the plurality of heat dissipation fins or measuring a distance from the floor of the test water jacket to a back surface of the metal base, and
adjusting the lengths of the plurality of heat dissipation fins so that the measured distances become constant.

10. The method according to claim 9, wherein the adjusting includes:
adjusting a length L(x) of each of the plurality of heat dissipation fins to satisfy L(x)=L(0)+(C(x)−C(0)), wherein
x is a position of said each of the plurality of heat dissipation fins,
L(0) is a length of one of the plurality of heat dissipation fins that is closest to one of the ends,
C(x) is a distance from the floor of the test water jacket to the tip of said each of the plurality of heat dissipation fins at the position x, and
C(0) is a distance from the floor of the test water jacket to the tip of said closest one of the plurality of heat dissipation fins.
